(19) United States
(12) Patent Application Publication
(10) Pub. No.: US 2005/0249363 A1
(43) Pub. Date: Nov. 10, 2005

(54) Signal processing method for audio signal compensation

(76) Inventors: Wen-Chieh Lee, Taipei (TW); Chi-Min Liu, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/116,239

(22) Filed: Apr. 28, 2005

(30) Foreign Application Priority Data
May 4, 2004 (TW) 93112529

(51) Int. Cl. H03G 5/00; H03G 3/00

(52) U.S. Cl. 381/98; 381/61

(57) ABSTRACT

A signal processing method for audio signal compensation that corrects the high frequency audio signals while displaying music being removed with the high frequency audio signals is disclosed. When music being deleted with high-frequency audio signal is displayed, the deleted high-frequency audio signals are compensated by this method. At first, a first audio signal is inputted. Then increase output speed of the received first audio signal for outputting and producing a second audio signal. Sample a high frequency audio signal from the second audio signal and use this high frequency audio signal in compensation of the first audio signal, then output the compensated audio signal. Thus the quality of audio signals is improved and audio enjoyment for audience is increased.

### BACKGROUND OF THE INVENTION

The present invention relates to a signal processing method for audio signal compensation, especially to a method that compensates audio signal loss in high frequency for improving audio quality as well as enhancing sensational enjoyment.

Due to fast development of technology and pressures of recession, modern people lives under high competitive environment. There it is an important issue to relieve physical and emotional hardship. Most of people relax from the pressure by listening music. People's hearts move to the rhythm thus harmonic music makes people peaceful and calm. Thus playing music for employees enjoyment in the workplace will release their pressure and improve their work efficiency. At leisure time, listening to the music also calms down the working tension, reduce life stress, enhance physical and mental health, and prevent various chronic diseases. The power of music is beyond our imagination. Therefore, music is one of the most important entertainments.

In the era of information technology, in order to save more music data in storage devices such as optical disks, memory cards, hard disks and for the convenience of transmission, music data with larger file format such as CD (compact disk) is compressed and converted into compressed file format for music such as MP3(MPEG-1 Audio Layer-3) AAC(Advanced Audio coding). However, during the process of compression, the high frequency that is imperceptible to the human ear is deleted and thereby to reduce the size of the data stream. Although the size of the compressed music files is reduced, there is a loss of high frequency fidelity that has negative effect on audio enjoyment of audience.

Refer to FIG. 1A & FIG. 1B, they show the frequency verses amplitude figures for audio signals of original music and music compressed audio. In FIG. 1A, it consists of a low-mid audio frequency range 10 and a high audio frequency range 15. In order to reduce the size of music files for the convenience of storage, the audio signals of the high audio frequency range 15 are deleted and then the compression is continued. As shown in FIG. 1B, while playing the compressed music, the frequency vs amplitude chart only has the low-mid audio frequency range 10 while the high-frequency audio signals are lost. Thus this is a shortage for audience with sensitive sense of hearing.

### SUMMARY OF THE INVENTION

Therefore it is a primary object of the present invention to provide a signal processing method for audio signal compensation that adds correction signals for the high-frequency range to cover for the loss of high-frequency audio signals for enhancing audience's audio enjoyment.

When users display the music with high-frequency losses, a method in accordance with the present invention includes following steps: firstly, input a first audio signal intended to be compensated. Then increase output speed of the first audio signal so as to output and produce a second audio signal. Find out high frequency audio signal of the second audio signal. At last, add the high frequency audio signal into the first audio signal and then output as well as display them together. Thus the audio signal being outputted has been covered for the high frequency range so that the music is near original audio signal and audience has better audio enjoyment for releasing physical and mental pressure.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1A is a frequency verses amplitude figure for audio signals of original music;

FIG. 1B is a frequency verses amplitude figure for audio signals of a compressed music file;

FIG. 2 is a flow chart of an embodiment in accordance with the present invention;

FIG. 3A is a time verses amplitude chart of outputted audio signal of the compressed file format for music;

FIG. 3B is a time verses amplitude chart of sampling points of simulate audio signal sampling from the audio signal in FIG. 3A;

FIG. 3C is a time verses amplitude chart of a second audio signal being produced from the sampling points of the simulated audio signal in FIG. 3B outputted in a higher speed than the input speed of the audio signal in FIG. 3A;

FIG. 3D is a frequency verses amplitude figure of FIG. 3C;

FIG. 3E is a frequency verses amplitude figure of FIG. 3C after being compensated;

FIG. 3 F is a frequency verses amplitude figure of high frequency audio signal in FIG. 3E;

FIG. 4 is a frequency verses amplitude figure of FIG. 3A after compensation of high-frequency audio signal;

FIG. 5 is a flow chart of another embodiment in accordance with the present invention.

### DETAILED DESCRIPTION OF THE PREFFERED EMBODIMENT

By increasing the output speed of audio signals being compensated, the present invention outputs another audio signal, then find out the high-frequency signals in this further audio signal to compensate the loss of high audio frequency range in original audio signals and outputs the compensated audio signals for displaying so that the audio signals are reconstructed and a better audio quality reproduction is provided.

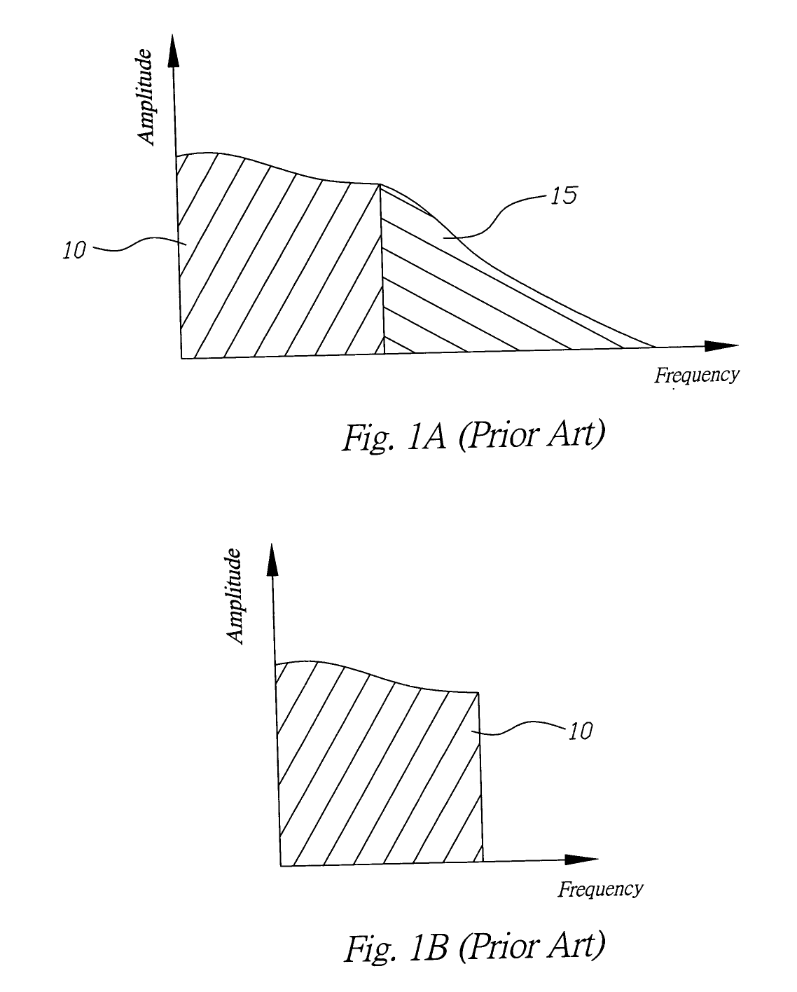

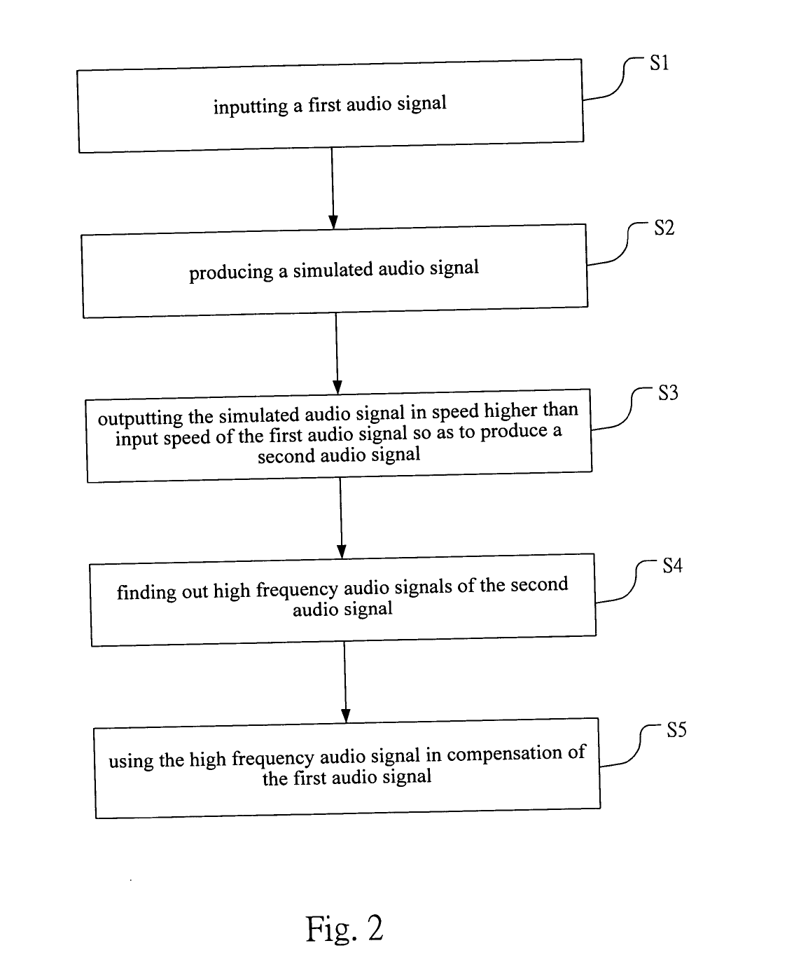

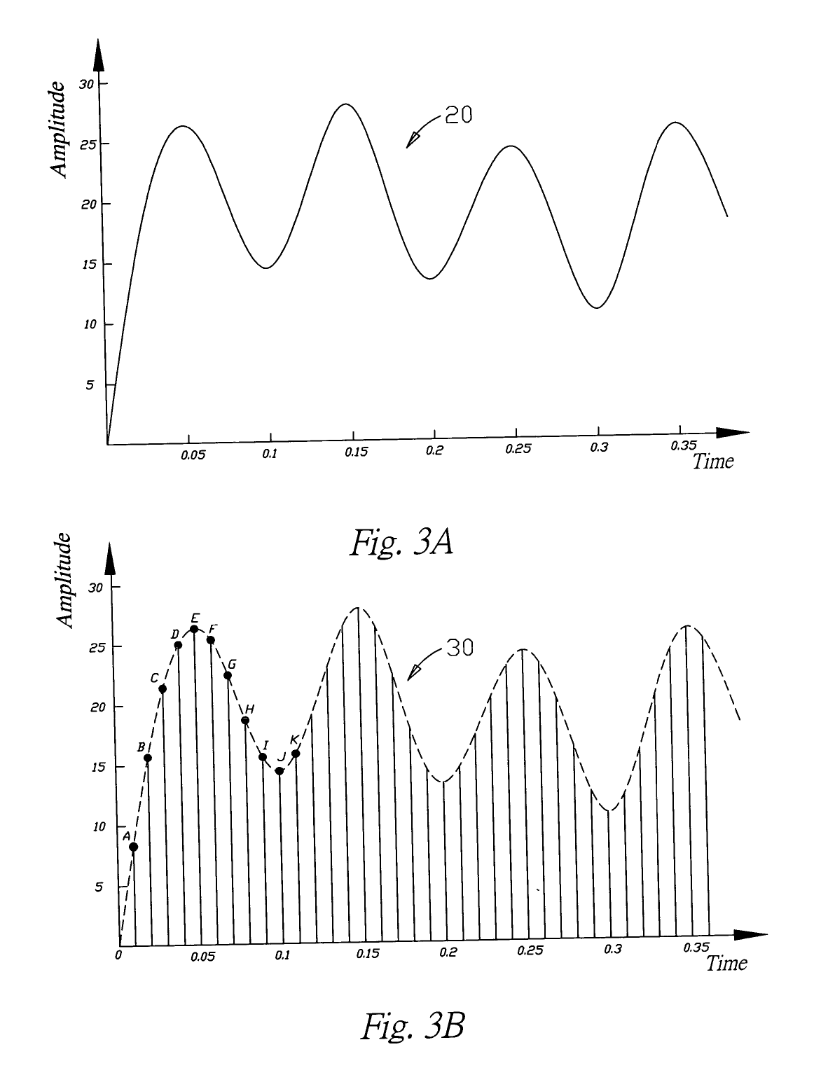

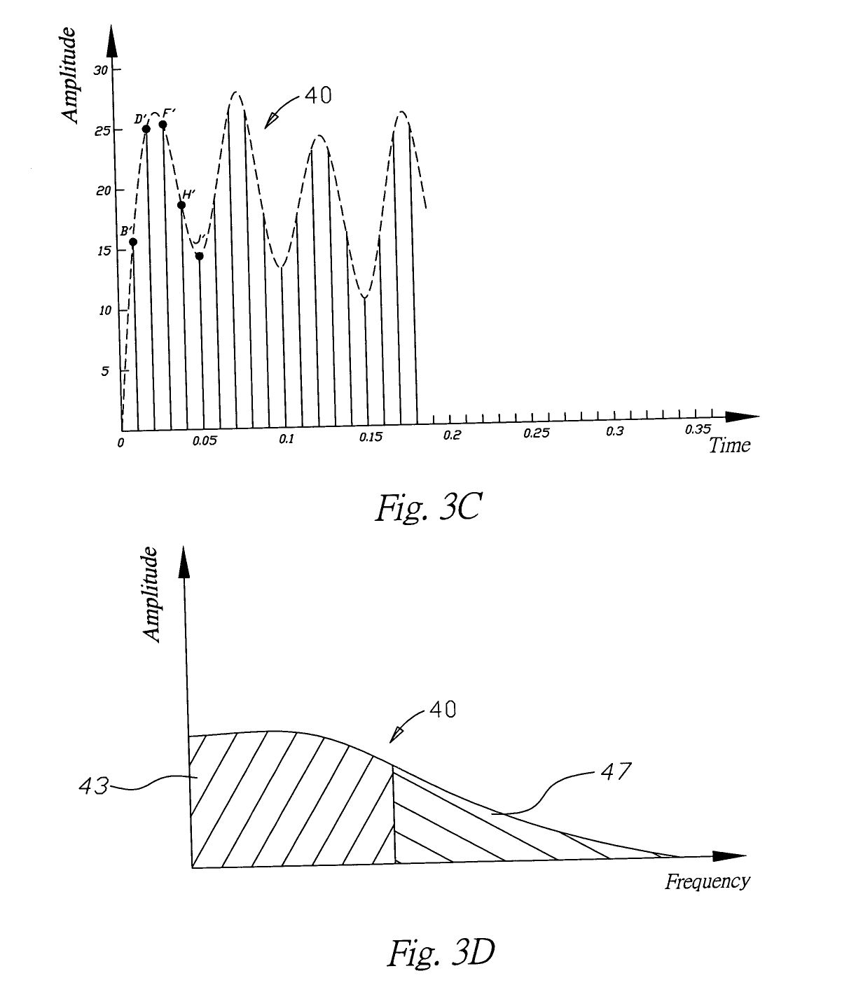

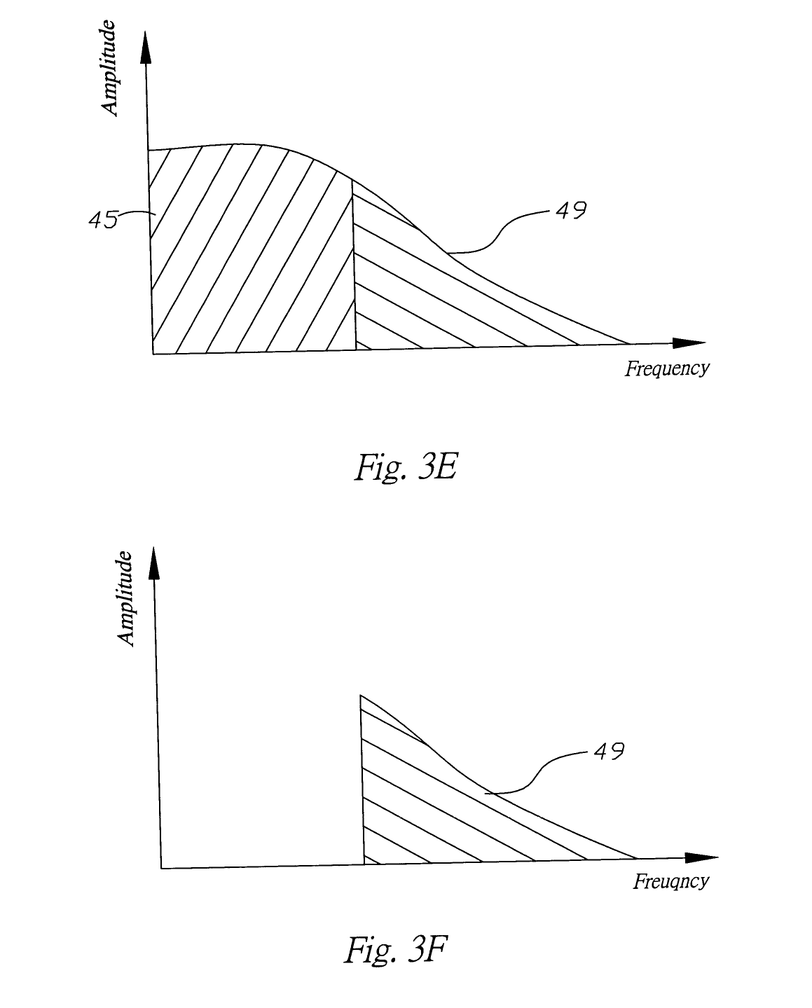

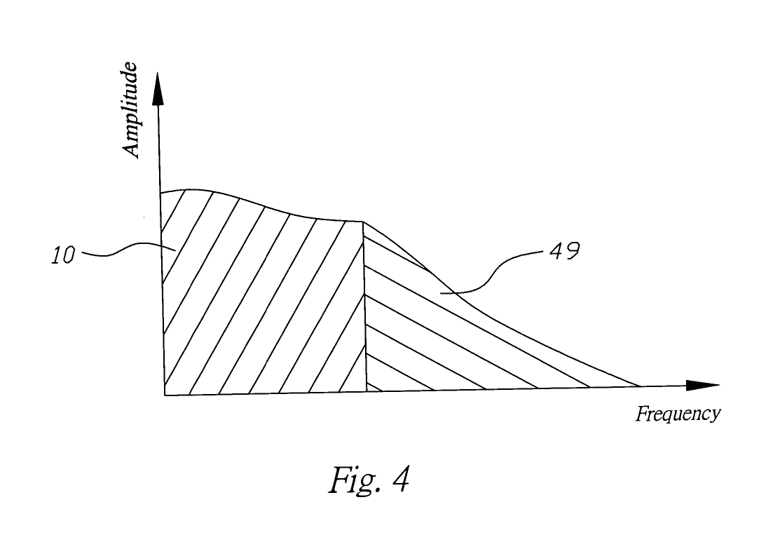

Refer to FIG. 2, FIG. 3A to FIG. 3F, & FIG. 4, when people play compressed music files such as MP3 or AAC, audio data in each range of the music file is outputted in sequence. The audio data means sampling points of digital audio signal. As shown in step S1, input a first audio signal 20 shown in FIG. 3A. The frequency verses amplitude chart of the first audio signal 20 is shown as FIG. 1B. At the same time of inputting the first audio signal 20, a proper sampling rate (sample/sec) is used to take samples of the first audio signal 20 for simulation of the first audio signal 20. For example, refer to FIG. 3B, the sampling rate is 100 sample/sec in this embodiment. A number of P sampling points A, B, C, D, E . . . of simulated audio signal are obtained in sequence so as to produce the simulated audio signal 30 as the dotted line shown in figure. The higher sampling rate, the more the simulated audio signal 30 is similar to the first audio signal 20. This is the step S2, the simulated audio signal 30 is produced.

Then the step S3, the number of P sampling points of the simulated audio signal 30 in FIG. 3B are outputted sequentially in higher speed than the input speed of the first audio signal 20. That is—output the simulated audio signal 30 quickly so as to produce a second audio signal 40 in FIG. 3C. In this embodiment, the output speed of the simulated audio signal 30 is twice of the input speed of the first audio signal 20 so that the output frequency of the simulated audio signal 30 is increased for producing the second audio signal 40 shown by the dotted line in FIG. 3C. The principle of this operation is that when people fast-forward the music, high-frequency sounds are produced. When sampling points of simulated audio signal are outputted, the same sampling rate—100 sample/sec—is used to sample the sound so as to obtain a number of Q sampling points of the second audio signal 40 such as B′, D′, F′ . . . sequentially. The amplitude of point B′ is the same with that of the point B. The amplitude of point D′ is the same with that of the point D. By analogy, it is applied to other sampling points.

Then, the step S4, find out high frequency audio signals of the second audio signal 40. The way to find out the signal—firstly, the second audio signal 40 in time domain is converted into frequency domain shown in FIG. 3D. The low-mid audio frequency range 43 and the high audio frequency range 47 in FIG. 3D is formed from the low-mid audio frequency range 10 in FIG. 1B. That is, the total area of the low-mid audio frequency range 43 and the high audio frequency range 47 is equal to the area of the low-mid audio frequency range 10. Due to the reduction of the frequency, it is necessary to compensate for the second audio signal 40 in frequency domain. After being compensated, as shown in FIG. 3E, the total area of the low-mid audio frequency range 45 and the high audio frequency range 49 is close to the total area in FIG. 1A. At last, as shown in FIG. 3F, the high audio frequency range 49 is cut off and converted into high frequency audio signals in time domain. Then, refer to step S5, the high frequency audio signals in time domain is added to the first audio signal 20 for improving high frequency performance and output then whole signal together.

In the step of S3, the output speed of the simulated audio signal 30 is increased for outputting, producing the second audio signal 40 and a number of Q sampling points thereof is obtained to be mapping to the frequency domain. Comparing FIG. 3A with FIG. 3C, the output time of the second audio signal 40 is half of that of the first audio signal 20 so that the number of sampling points-Q is only half of the number P. That is, Q=P/times of the output speed of sampling points of the simulated audio signal compared with the input speed of the first audio signal. In this embodiment, the output speed of sampling points of the simulated audio signal is two times of the input speed of the first audio signal 20. Thus the number of sampling points of the second audio signal-Q equals to P/2, half of the number P of sampling points of the simulated audio signal. Therefore, the time duration of the high frequency signal converted from the high audio frequency range 49 in FIG. 3F is only half of that of the first audio signal 20. In continuing step S5, the high frequency audio signal need to be reproduced and then added to the converted high frequency audio signal in time domain so as to make the time duration of the high frequency audio signal equal to that of the first audio signal 20. Finally, the corrected high frequency audio signal is added to the first audio signal 20 for being outputted. The frequency verses amplitude chart of the outputted audio signal as shown in FIG. 4 includes the low-mid audio frequency range 10 in FIG. 1B and the high audio frequency range 49 in FIG. 3F.

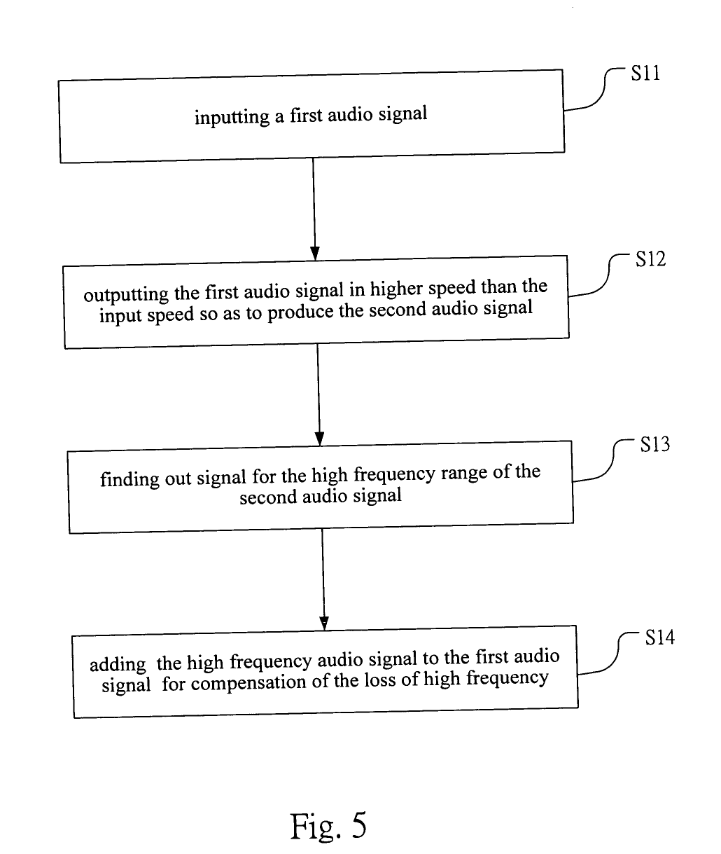

Refer to FIG. 5, a flow chart of another embodiment in accordance with the present invention is disclosed. Due to the popularity of compressed music files such as MP3 or AAC, the sampling rate has become a general specification. Thus when displaying the compressed music file, the flow chart for compensation the high-frequency cutoffs is as shown in FIG. 5. The difference between this embodiment and above one is that the first audio signal 20 being inputted in step S11 is produced from audio information with known sampling rate—that is a plurality of sampling points of the audio signal. Thus there is no need to use proper sampling rate to take samples of the first audio signal 20 for obtaining a number of P of audio signal sampling points and producing a simulated audio signal 30, as shown in step S2. Then jump to step S12, output the first audio signal 20 in higher speed than the input speed thereof so as to produce the second audio signal 40. While outputting the second audio signal 40, use the sampling rate already known to take a number of Q sampling points of the second audio signal 40 sequentially. Then refer to step S13, find out signal for the high frequency range of the second audio signal 40 and then add it to the first audio frequency 20 for compensation of the loss of high frequency, being outputted together, as shown in step S14.

In summary, the present invention provides a signal processing method for audio signal compensation that improves the high frequency performance while displaying music with high-frequency losses so as to achieve originality and integral of music for better audio enjoyment.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

1. A signal processing method for audio signal compensation comprising the steps of:
inputting a first audio signal;
increasing output speed of the first audio signal for outputting and producing a second audio signal;
reading a high frequency audio signal of the second audio signal; and
using the high frequency audio signal in compensation of the first audio signal and then outputting the compensated audio signal.

2. The method as claimed in claim 1, wherein after step of inputting a first audio signal, producing a simulated audio signal that simulated the first audio signal and then outputting the simulated audio signal in speed higher than input speed of the first audio signal so as to produce the second audio signal.

3. The method as claimed in claim 2, wherein the first audio signal is signal in time domain and the step of producing the simulated audio signal further having a step—using a proper sampling rate to take samples from the first audio signal for obtaining a plurality of sampling points of simulated audio signal sequentially to produce a simulated audio signal; then outputting the simulated audio signal in speed higher than input speed of the first audio signal for producing the second audio signal.

4. The method as claimed in claim 3, wherein the step of producing the second audio signal further comprising a step—while outputting the second audio signal, using the same sampling rate to take samples from the second audio signal for obtaining a plurality of sampling points sequentially of the second audio signal, converting the second audio signal into audio signal in frequency domain, compensating the second audio signal in frequency domain, reading high frequency audio signal of the compensated second audio signal and adding the high frequency audio signal of the compensated second audio signal into the first audio signal to cover for high frequency losses.

5. The method as claimed in claim 1, wherein the first audio signal is an audio signal in time domain and sampling rate of sampling points of the first audio signal is already known; the step of increasing output speed of the first audio signal for outputting and producing a second audio signal further having a step: while outputting the second audio signal, using the sampling rate already known to take samples from the second audio signal for obtaining a plurality of sampling points sequentially of the second audio signal, converting the second audio signal into audio signal in frequency domain, compensating the second audio signal in frequency domain, reading high frequency audio signal of the compensated second audio signal and adding the high frequency audio signal of the compensated second audio signal into the first audio signal to cover for high frequency losses.

6. The method as claimed in claim 4, wherein the step of adding the high frequency audio signal of the compensated second audio signal into the first audio signal to cover for high frequency losses further comprising the steps of:
converting high frequency audio signal in frequency domain into high frequency audio signal in time domain;
replicating the high frequency audio signal in time domain and compensating it into the converted high frequency audio signal in time domain; and
adding the compensated high frequency audio signal in time domain into the first audio signal and outputting them together.

7. The method as claimed in claim 5, wherein the step of adding the high frequency audio signal of the compensated second audio signal into the first audio signal to cover for high frequency losses further comprising the steps of:
converting high frequency audio signal in frequency domain into high frequency audio signal in time domain;
replicating the high frequency audio signal in time domain and compensating it into the converted high frequency audio signal in time domain; and
adding the compensated high frequency audio signal in time domain into the first audio signal and outputting them together.

8. The method as claimed in claim 1, wherein the first audio signal is an audio signal for displaying a compressed file format for music.

9. The method as claimed in claim 7, wherein the compressed file format for music is MPEG-1 Audio Layer-3 (MP3).

10. The method as claimed in claim 7, wherein the compressed file format for music is advanced audio coding (AAC).
